(19) United States
(12) Patent Application Publication
(10) Pub. No.: US 2025/0016978 A1
(43) Pub. Date: Jan. 9, 2025

(54) CAPACITOR STRUCTURE AND SEMICONDUCTOR MEMORY DEVICE INCLUDING THE SAME

(71) Applicant: Samsung Electronics Co., Ltd., Suwon-si (KR)

(72) Inventors: Jung Min PARK, Suwon-si (KR); Ji-Sung KIM, Suwon-si (KR); Hae Ryong KIM, Suwon-si (KR); Bo-Eun PARK, Suwon-si (KR); Han Jin LIM, Suwon-si (KR); Hyung Suk JUNG, Suwon-si (KR)

(21) Appl. No.: 18/613,471

(22) Filed: Mar. 22, 2024

(30) Foreign Application Priority Data
Jul. 6, 2023 (KR) 10-2023-0087500

(51) Int. Cl. H10B 12/00

(52) U.S. Cl. CPC H10B 12/315; H01L 28/65; H01L 28/75

(57) ABSTRACT

A capacitor structure is provided. The capacitor structure comprises an upper electrode, a lower electrode including a lower electrode film and a lower interface electrode film, a capacitor dielectric film between the lower electrode and the upper electrode, and an interface blocking film between the lower electrode and the capacitor dielectric film, the interface blocking film being in contact with the capacitor dielectric film and the lower interface electrode film, wherein the interface blocking film includes a first metal oxide containing a first metal element, the lower interface electrode film includes a second conductive metal oxide containing a second metal element different from the first metal element, the capacitor dielectric film does not include the first metal oxide, and a thickness of the lower interface electrode film is greater than that of the interface blocking film.

### CROSS-REFERENCE TO RELATED APPLICATION

This application claims priority from Korean Patent Application No. 10-2023-0087500 filed on Jul. 6, 2023 in the Korean Intellectual Property Office and all the benefits accruing therefrom under 35 U.S.C. 119, the contents of which in its entirety are herein incorporated by reference.

### BACKGROUND

### Technical Field

The present disclosure relates to a capacitor structure and a semiconductor memory device including the same.

### Description of the Related Art

Recently, as semiconductor devices have become large-capacity and highly integrated, design rules are also continuously decreasing. This trend is also seen in a DRAM, which is one of memory semiconductor devices. In order for a DRAM device to operate, a certain level of capacitance is required for each cell.

The increase in capacitance increases the amount of charge stored in a capacitor, resulting in improved refresh characteristics of the semiconductor device. The improved refresh characteristics of the semiconductor device may improve yield of the semiconductor device.

To increase capacitance, a method of using a dielectric film having a high dielectric constant in a capacitor or increasing a contact area between a lower electrode of the capacitor and the dielectric film is being studied.

### BRIEF SUMMARY

Aspects of the present disclosure provide a semiconductor device capable of improving performance and reliability of an element.

According to some aspects of the present inventive concept, a capacitor structure includes an upper electrode; a lower electrode including a lower electrode film and a lower interface electrode film; a capacitor dielectric film between the lower electrode and the upper electrode; and an interface blocking film between the lower electrode and the capacitor dielectric film, the interface blocking film being in contact with the capacitor dielectric film and the lower interface electrode film, wherein the interface blocking film includes a first metal oxide containing a first metal element, the lower interface electrode film includes a second conductive metal oxide containing a second metal element different from the first metal element, the capacitor dielectric film does not include the first metal oxide, and a thickness of the lower interface electrode film is greater than a thickness of the interface blocking film.

According to some aspects of the present inventive concept, a capacitor structure includes an upper electrode; a lower electrode including a lower electrode film, a lower interface electrode film, and a lower insertion electrode film between the lower electrode film and the lower interface electrode film; a capacitor dielectric film between the lower electrode and the upper electrode; and an interface blocking film between the lower electrode and the capacitor dielectric film, the interface blocking film being in contact with the capacitor dielectric film and the lower interface electrode film, wherein the interface blocking film includes a first metal oxide containing a first metal element, the lower interface electrode film includes a second conductive metal oxide containing a second metal element different from the first metal element, the lower electrode film includes a third metal element, and the lower insertion electrode film includes a third metal oxide containing the third metal element.

According to some aspects of the present inventive concept, a semiconductor memory device includes a substrate including an active region defined by an element isolation, the active region extending in a first direction and including a first portion and a second portion defined on both sides of the first portion; a word line extended in a second direction different from the first direction in the substrate and the element isolation film, the word line crossing between the first portion of the active region and the second portion of the active region; a bit line contact connected to the first portion of the active region; a bit line connected to the bit line contact on the bit line contact and extended in a third direction different from the first direction and the second direction; and a capacitor structure including a lower electrode and an interface blocking film, a capacitor dielectric film and an upper electrode, which are sequentially stacked on the lower electrode, the lower electrode being connected to the second portion of the active region, wherein the lower electrode includes: a lower electrode film connected to the second portion of the active region, the lower electrode film including a first metal element; a lower insertion electrode film including a first metal oxide containing the first metal element; and a lower interface electrode film including a second conductive metal oxide containing a second metal element, the interface blocking film is in contact with the lower interface electrode film and the capacitor dielectric film, and includes a third metal oxide containing a third metal element different from the second metal element, and a thickness of the lower interface electrode film is greater than a thickness of the lower insertion electrode film and a thickness of the interface blocking film.

According to some aspects of the present inventive concept, a method of fabricating a capacitor structure includes providing a lower insulating film on a substrate; providing a lower electrode film on the lower insulating film; forming a lower insertion electrode film and a lower interface electrode film on the lower electrode film; forming an interface blocking film on the lower interface electrode film; forming a capacitor dielectric film on the interface blocking film; and forming an upper electrode on the capacitor dielectric film.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

FIG. 1 is an example view illustrating a capacitor structure according to some embodiments.

FIGS. 2 to 4 are graphs illustrating metal elements included in a lower electrode and an interface blocking film of FIG. 1.

FIG. 5 is an example view illustrating a capacitor structure according to some embodiments.

FIG. 6 is a schematic layout of a semiconductor memory device according to some embodiments.

FIG. 7 is a layout illustrating only a word line and a cell active region of FIG. 6.

FIG. 8 is an example cross-sectional view taken along line A-A of FIG. 6.

FIG. 9 is an example cross-sectional view taken along line B-B of FIG. 6.

FIG. 10 is an enlarged view illustrating a region P of FIG. 8.

FIGS. 11 to 13 are views illustrating a semiconductor memory device according to some embodiments.

FIG. 14 is a layout view illustrating a semiconductor memory device according to some embodiments.

FIG. 15 is a perspective view illustrating a semiconductor memory device according to some embodiments.

FIG. 16 is a cross-sectional view taken along lines C-C and D-D of FIG. 14.

FIG. 17 is an enlarged view illustrating a region Q of FIG. 16.

FIG. 18 is a layout view illustrating a semiconductor memory device according to some embodiments.

FIG. 19 is a perspective view illustrating a semiconductor memory device according to some embodiments.

FIGS. 20 to 23 are views illustrating intermediate steps to describe a method for fabricating a capacitor structure according to some embodiments.

### DETAILED DESCRIPTION OF THE DISCLOSURE

It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirit of the present disclosure.

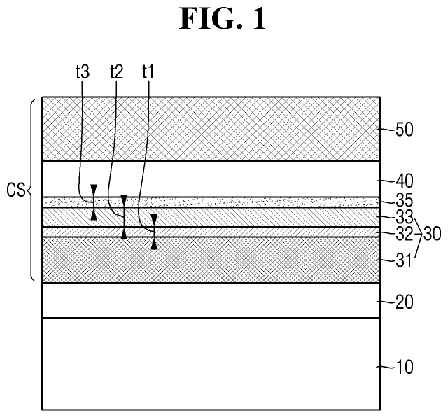

A capacitor structure according to some embodiments will be described with reference to FIGS. 1 to 4.

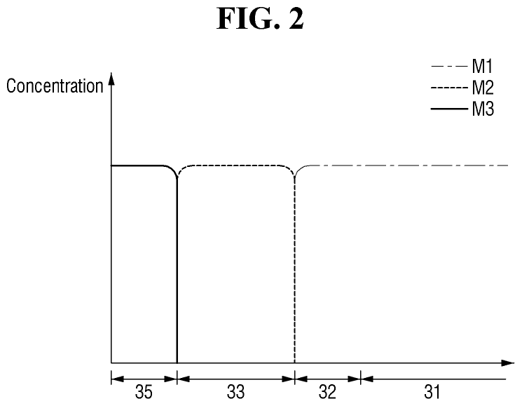

FIG. 1 is an example view illustrating a capacitor structure according to some embodiments. FIGS. 2 to 4 are graphs illustrating metal elements included in a lower electrode and an interface blocking film of FIG. 1.

Referring to FIGS. 1 to 4, a capacitor structure CS according to some embodiments may be disposed on a first substrate 10 and a lower insulating film 20.

The first substrate 10 may be a bulk silicon or a silicon-on-insulator (SOI). Alternatively, the first substrate 10 may be a silicon substrate, or may be or include other materials such as silicon germanium, silicon germanium on insulator (SGOI), indium antimonide, lead telluride, indium arsenide, indium phosphide, gallium arsenide or gallium antimonide, but is not limited thereto.

The lower insulating film 20 may be disposed on the first substrate 10. The lower insulating film 20 may be or include, for example, at least one of silicon oxide, silicon nitride, silicon oxynitride or a low-k material having a dielectric constant smaller than that of silicon oxide. The low-k material may include, but is not limited to, at least one of Flowable Oxide (FOX), Torene SilaZene (TOSZ), Undoped Silica Glass (USG), Borosilica Glass (BSG), PhosphoSilica Glass (PSG), BoroPhosphoSilica Glass (BPSG), Plasma Enhanced Tetra Ethyl Ortho Silicate (PETEOS), Fluoride Silicate Glass (FSG), Carbon Doped silicon Oxide (CDO), Xerogel, Aerogel, Amorphous Fluorinated Carbon, Organo Silicate Glass (OSG), Parylene, bis-benzocyclobutenes (BCB), SiLK, polyimide, porous polymeric material or their combination.

The capacitor structure CS may be disposed on the first substrate 10. The capacitor structure CS may include a lower electrode 30, an interface blocking film 35, a capacitor dielectric film 40, and an upper electrode 50.

The interface blocking film 35 and the capacitor dielectric film 40 are disposed between the lower electrode 30 and the upper electrode 50. The interface blocking film 35 is disposed between the lower electrode 30 and the capacitor dielectric film 40. The capacitor structure CS may store charges in the capacitor dielectric film 40 by using a potential difference generated between the lower electrode 30 and the upper electrode 50.

The lower electrode 30 may include a lower electrode film 31, a lower insertion electrode film 32, and a lower interface electrode film 33. The lower electrode film 31, the lower insertion electrode film 32 and the lower interface electrode film 33 may be sequentially stacked on the lower insulating film 20.

The lower electrode film 31 may be formed of or include a first metal element M1. The first metal element M1 may include at least one of, for example, titanium (Ti), tantalum (Ta), tungsten (W), ruthenium (Ru) or iridium (Ir), but is not limited thereto. In some embodiments, the lower electrode film 31 may be formed of or include a nitride of the first metal element M1. For example, the lower electrode film 31 may include titanium nitride.

The lower insertion electrode film 32 may be disposed on the lower electrode film 31. The lower insertion electrode film 32 may be disposed between the lower electrode film 31 and the lower interface electrode film 33. The lower insertion electrode film 32 is in contact with the lower electrode film 31.

The lower insertion electrode film 32 may be formed of or include a first metal oxide containing the first metal element M1. For example, when the first metal element M1 is titanium (Ti), the first metal oxide may be a titanium oxide. The lower insertion electrode film 32 may include titanium oxide. The lower insertion electrode film 32 may be a titanium oxide film.

For example, the lower insertion electrode film 32 may be formed by oxidizing the lower electrode film 31. For another example, the lower insertion electrode film 32 may be formed using a deposition process.

The lower interface electrode film 33 may be disposed on the lower insertion electrode film 32. The lower interface electrode film 33 may be in contact with the lower insertion electrode film 32.

The lower interface electrode film 33 may include a conductive material. The lower interface electrode film 33 may include a metal oxide containing a metal element. For example, the lower interface electrode film 33 may include a conductive metal oxide.

For example, in FIG. 2, the metal element included in the lower interface electrode film 33 may be a second metal element M2. The lower interface electrode film 33 may include a second metal oxide containing the second metal element M2. The second metal element M2 is different from the first metal element M1.

The second metal element M2 may include at least one of indium (In), ruthenium (Ru), iridium (Ir), vanadium (V), tin (Sn), zinc (Zn), nickel (Ni), tungsten (W) or molybdenum (Mo). The second metal oxide may include at least one of indium oxide, ruthenium oxide, iridium oxide, vanadium oxide, tin oxide, zinc oxide, nickel oxide, tungsten oxide or molybdenum oxide. However, the type of the second metal element M2 is not limited to the above-described metal element. That is, a metal element included in a metal oxide that has conductivity may correspond to the second metal element M2.

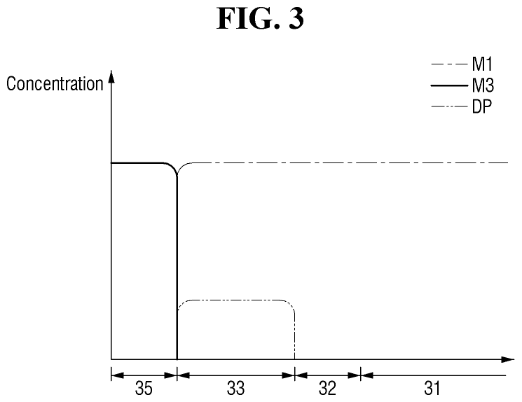

For another example, in FIG. 3, the metal element included in the lower interface electrode film 33 may be the first metal element M1. The lower interface electrode film 33 may include a first metal oxide containing the first metal element M1. The metal oxide included in the lower interface electrode film 33 may be the same as a metal oxide included in the lower insertion electrode film 32. When the first metal element M1 is titanium (Ti), the lower interface electrode film 33 may include titanium oxide. The first metal oxide included in the lower interface electrode film 33 may be titanium oxide.

The lower interface electrode film 33 may include a doping element DP. The lower interface electrode film 33 may include a first metal oxide doped with a doping element DP.

The doping element DP may include a first impurity element. The first impurity element may be a metal element. For example, the first impurity element may include at least one element from among groups 5 to 11 and 15 metal elements. For example, the first impurity element may include at least one of antimony (Sb), molybdenum (Mo), cobalt (Co), niobium (Nb), copper (Cu), nickel (Ni) or tantalum (Ta), but is not limited thereto. The lower interface electrode film 33 may include the first impurity element at an atomic percentage of 10 atomic percent (at %) or less. For example, a content of the first impurity element in the lower interface electrode film 33 may be 0.01 at % to 10 at %. Preferably, the content of the first impurity element may be 0.01 at % to 1 at %.

The doping element DP may further include a second impurity element. The doping element DP may include a first impurity element and a second impurity element. For example, the doping element DP may include at least one of silicon (Si), aluminum (Al), zirconium (Zr) or hafnium (Hf). A content of the second impurity element included in the lower interface electrode film 33 may be smaller than the content of the first impurity element included in the lower interface electrode film 33.

For example, the lower interface electrode film 33 may be or include a first metal oxide doped with the first impurity element. For another example, the lower interface electrode film 33 may be or include a first metal oxide doped with the first impurity element and the second impurity element.

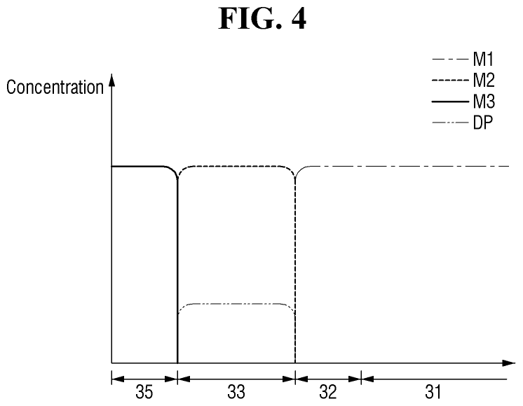

For another example, in FIG. 4, the metal element included in the lower interface electrode film 33 may be a second metal element M2 different from the first metal element M1. The lower interface electrode film 33 may include a second metal oxide containing the second metal element M2. The lower interface electrode film 33 may include a second metal oxide doped with the doping element DP. The doping element DP may include the first impurity element. The lower interface electrode film 33 may include a second metal oxide doped with the first impurity element.

The second metal element M2 may include at least one of indium (In), ruthenium (Ru), iridium (Ir), vanadium (V), tin (Sn), zinc (Zn), nickel (Ni), tungsten (W) or molybdenum (Mo). The first impurity element may include at least one element from among groups 5 to 11 and 15 metal elements. For example, the first impurity element may include at least one of antimony (Sb), molybdenum (Mo), cobalt (Co), niobium (Nb), copper (Cu), nickel (Ni) or tantalum (Ta), but is not limited thereto.

The interface blocking film 35 may be disposed on the lower electrode 30. The interface blocking film 35 is disposed between the lower interface electrode film 33 and the capacitor dielectric film 40. The interface blocking film 35 is in contact with the lower interface electrode film 33 and the capacitor dielectric film 40.

The interface blocking film 35 may be formed of or include a third metal element M3. For example, the interface blocking film 35 may be formed of or include a third metal oxide containing a third metal element M3.

The third metal oxide may be, for example, a single metal oxide. In this case, the single metal oxide may be a binary compound composed of one metal and one oxygen. In addition, the single metal oxide does not mean that impurities are not included in the metal oxide.

The third metal element M3 is different from the metal element included in the lower interface electrode film 33. That is, the third metal oxide is different from the metal oxide included in the lower interface electrode film 33.

For example, when the metal element included in the lower interface electrode film 33 is different from the metal element included in the lower insertion electrode film 31, the third metal element M3 is different from the second metal element M2. The third metal element M3 may be different from or the same as the first metal element M1.

For another example, when the metal element included in the lower interface electrode film 33 is the same as the metal element included in the lower insertion electrode film 31, the third metal element M3 is different from the first metal element M1.

The third metal element M3 may include a transition metal element. The third metal element M3 may include one of tin (Sn), titanium (Ti), nickel (Ni), cobalt (Co) and molybdenum (Mo), but is not limited thereto.

A thickness t2 of the lower interface electrode film 33 is greater than a thickness t1 of the lower insertion electrode film 32 and a thickness t3 of the interface blocking film 35. The thickness t1 of the lower insertion electrode film 32 may be, for example, 10 Å or less. The thickness t3 of the interface blocking film 35 may be, for example, 10 Å or less. The thickness t2 of the lower interface electrode film 33 may be 5 Å to 20 Å. When the thickness t3 of the interface blocking film 35 is greater than 10 Å, the interface blocking film 35 may serve as a dielectric film. In this case, capacitance of the capacitor structure CS is reduced.

FIGS. 2 to 4 show the presence or absence of the first metal element M1, the second metal element M2 and the third metal element M3, but do not show a relative content difference. Referring to FIG. 2, the lower insertion electrode film 32 includes the first metal element M1, and the lower interface electrode film 33 includes the second metal element M2. A peak height of the first metal element M1 is the same as a peak height of the second metal element M2, but it does not mean that a concentration of the first metal element M1 in the lower insertion electrode film 32 is the same as that of the second metal element in the lower interface electrode film 33.

Meanwhile, FIGS. 3 and 4 show a relative content difference between the metal elements M1 and M2 and the doping element DP in the same film. That is, since the peak height of the metal elements M1 and M2 in the lower interface electrode film 33 is greater than a height of the doping element DP, the concentrations of the metal elements M1 and M2 in the lower interface electrode film 33 are higher than that of the doping element DP in the lower interface electrode film 33.

The capacitor dielectric film 40 may be disposed on the interface blocking film 35. The capacitor dielectric film 40 is disposed between the interface blocking film 35 and the upper electrode 50.

The capacitor dielectric film 40 may be formed of or include a metal oxide. In some embodiments, the capacitor dielectric film 40 does not include a third metal oxide included in the interface blocking film 35.

The capacitor dielectric film 40 may include at least one of, for example, silicon oxide, silicon nitride, silicon oxynitride, hafnium oxide, hafnium silicon oxide, hafnium zirconium oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, lead zirconium titanium oxide, yttrium oxide, aluminum oxide, lead scandium tantalum oxide, lead zinc niobate or their combination, but is not limited thereto.

The capacitor dielectric film 40 may include at least one of a ferroelectric material, an antiferroelectric material or a paraelectric material. For example, the capacitor dielectric film 40 may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, an antiferroelectric material and a paraelectric material.

The capacitor dielectric film 40 may include combinations of various materials as described above. Hereinafter, one of combinations of various materials that may be included in the capacitor dielectric film 40 will be described.

For example, the capacitor dielectric film 40 may include a combination of a ferroelectric material layer and a paraelectric material layer. Although the following description is an example of a ferroelectric material layer and a paraelectric material layer, the technical spirit of the present disclosure is not limited thereto.

The ferroelectric material layer may have ferroelectric characteristics. The ferroelectric material layer may include at least one of, for example, hafnium oxide, hafnium zirconium oxide, barium strontium titanium oxide, barium titanium oxide or lead zirconium titanium oxide. In this case, for example, the hafnium zirconium oxide may be a material doped with zirconium (Zr) in hafnium oxide. For another example, the hafnium zirconium oxide may be a compound of hafnium (Hf) and zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al) or yttrium (Y).

When the dopant is aluminum (Al), the ferroelectric material layer may include aluminum of 3 at % to 8 at %. In this case, a ratio of the dopant may be a ratio of aluminum to a sum of hafnium and aluminum.

When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. The paraelectric material layer may include at least one of, for example, silicon oxide or metal oxide having a high dielectric constant. The metal oxide included in the paraelectric material layer may include, but is not limited to, at least one of hafnium oxide, zirconium oxide or aluminum oxide.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The upper electrode 50 may be disposed on the capacitor dielectric film 40. The upper electrode 50 may be or include at least one of, for example, titanium, titanium nitride, tantalum, tantalum nitride, tungsten, tungsten nitride or ruthenium. In some embodiments, the upper electrode 50 may include the first metal element M1. For example, the upper electrode 50 may include titanium nitride.

When the lower electrode 30 and the capacitor dielectric film 40 form a boundary, an oxygen vacancy may be generated in the capacitor dielectric film 40 near the boundary between the lower electrode 30 and the capacitor dielectric film 40. The oxygen vacancy generated in the capacitor dielectric film 40 may degrade dielectric characteristics of the capacitor dielectric film 40. Also, the oxygen vacancy generated in the capacitor dielectric film 40 may lower capacitance of the capacitor dielectric film 40. In addition, the oxygen vacancy generated in the capacitor dielectric film 40 lowers crystallinity of the capacitor dielectric film 40, thereby increasing a crystallization temperature of the capacitor dielectric film 40.

As the capacitor structure CS according to some embodiments includes the interface blocking film 35, the interface blocking film 35 may suppress the generation of the oxygen vacancy in the capacitor dielectric film 40. Further, the interface blocking film 35 may serve to reduce the oxygen vacancy by supplying oxygen to the capacitor dielectric film 40. That is, the interface blocking film 35 may serve to supply oxygen to the capacitor dielectric film 40. The interface blocking film 35 may prevent the dielectric characteristics of the capacitor dielectric film 40 from being deteriorated. Also, the interface blocking film 35 may prevent the capacitance of the capacitor dielectric film 40 from being lowered. In addition, the interface blocking film 35 may lower the crystallization temperature of the capacitor dielectric film 40.

The lower electrode 30 and the capacitor dielectric film 40 may have their respective thermal characteristics different from each other. That is, abnormal stress may be generated between the lower electrode 30 and the capacitor dielectric film 40. The lower electrode 30 and the like may be bent due to the abnormal stress between the lower electrode 30 and the capacitor dielectric film 40.

As the capacitor structure CS according to some embodiments includes the interface blocking film 35, the interface blocking film 35 may relieve stress between the lower electrode 30 and the capacitor dielectric film 40. That is, the interface blocking film 35 may improve bending between the lower electrode 30 and the capacitor dielectric film 40.

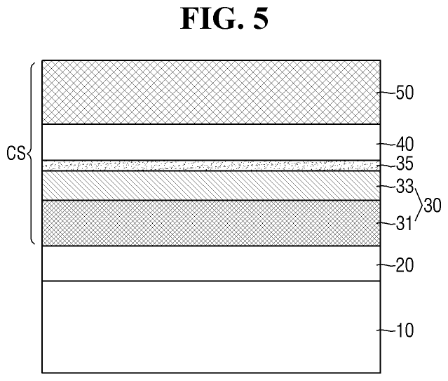

FIG. 5 is an example view illustrating a capacitor structure according to some embodiments. For convenience of description, the following description will be based on differences from the description made with reference to FIGS. 1 to 4.

Referring to FIG. 5, in the capacitor structure according to some embodiments, the lower electrode 30 includes a lower electrode film 31 and a lower interface electrode film 33.

The lower electrode 30 may not include the lower insertion electrode film 32 described above with reference to FIG. 1. For example, the lower interface electrode film 33 may be disposed directly on the lower electrode film 31.

The capacitor structure CS is similar to that described above with reference to FIG. 1 except that the lower insertion electrode film 32 is not interposed between the lower electrode film 31 and the lower interface electrode film 33.

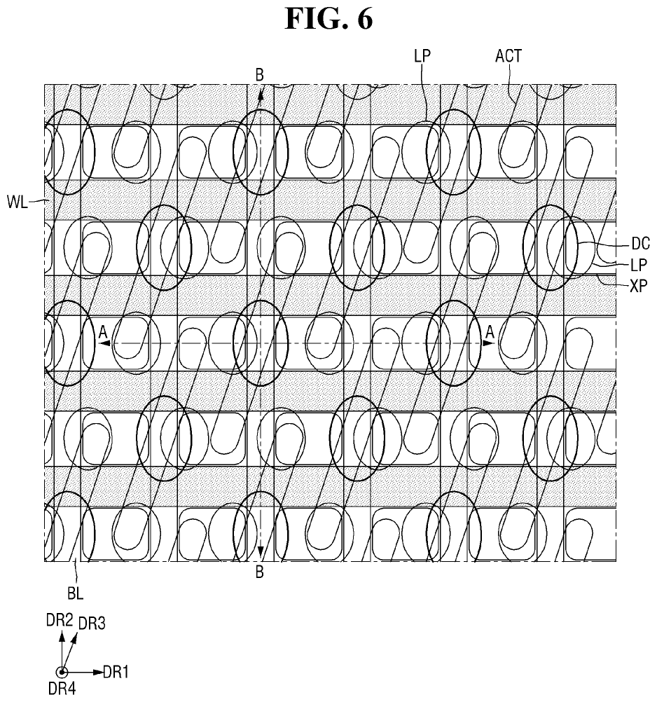

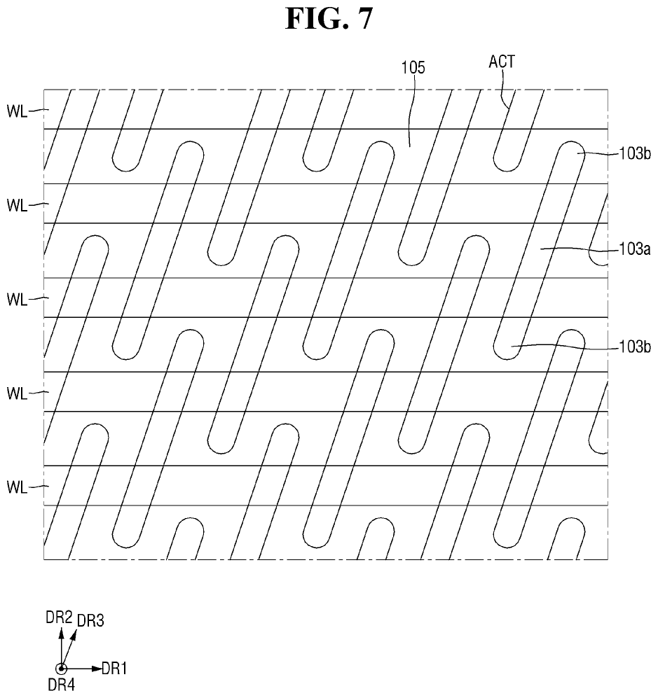

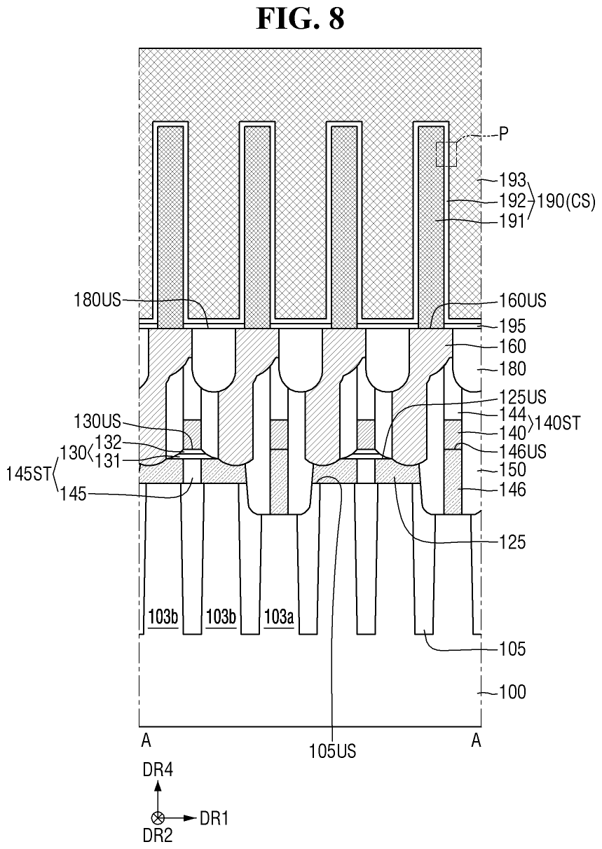

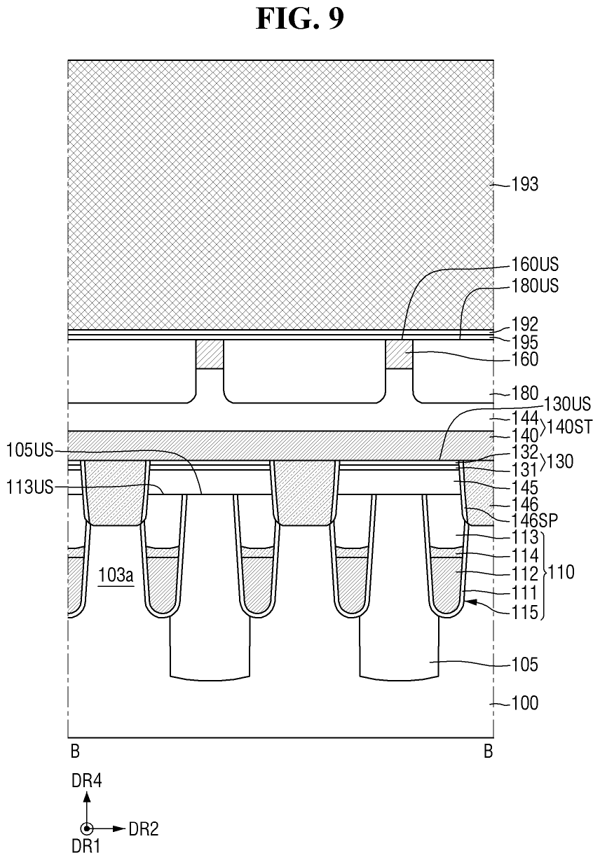

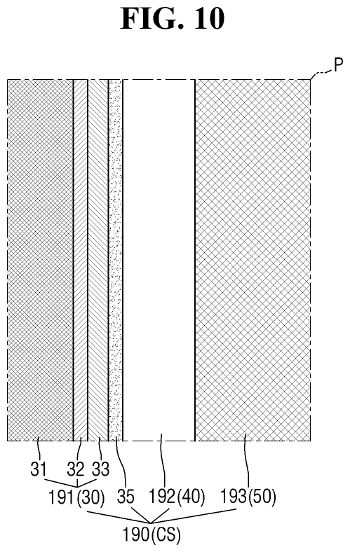

FIG. 6 is a schematic layout of a semiconductor memory device according to some embodiments. FIG. 7 is a layout illustrating only a word line and a cell active region of FIG. 6. FIG. 8 is an example cross-sectional view taken along line A-A of FIG. 6. FIG. 9 is an example cross-sectional view taken along line B-B of FIG. 6. FIG. 10 is an enlarged view illustrating a region P of FIG. 8. For convenience of description, redundant portions to those described with reference to FIGS. 1 to 5 will be briefly described or omitted.

In the drawings related to the semiconductor memory device according to some embodiments, a Dynamic Random Access Memory (DRAM) is shown, but is not limited thereto.

Referring to FIGS. 6 and 7, the semiconductor memory device according to some embodiments may include a plurality of active regions ACT.

The cell active region ACT may be defined by a cell element isolation film 105 formed in a second substrate (100 of FIG. 8). As the design rule of the semiconductor memory device is reduced, the cell active region ACT may be disposed in a bar shape of a diagonal line or an oblique line. For example, the cell active region ACT may be extended in a third direction DR3 different from both the first direction DR1 and the second direction DR2.

A plurality of gate electrodes extended in a first direction DR1 may be disposed across the cell active region ACT. The plurality of gate electrodes may be extended in parallel with each other. The plurality of gate electrodes may be, for example, a plurality of word lines WL. The word lines WL may be disposed at constant intervals. A width of the word line WL or an interval between the word lines WL may be determined in accordance with the design rule.

Each cell active region ACT may be divided into three portions by two word lines WL extended in the first direction DR1. The cell active region ACT may include a storage connection region 103b and a bit line connection region 103a. The bit line connection region 103a may be positioned at the center of the cell active region ACT, and the storage connection region 103b may be positioned at the end of the cell active region ACT.

For example, the bit line connection region 103a may be a region connected to a bit line BL, and the storage connection region 103b may be a region connected to a first capacitor structure (190 of FIG. 8). In other words, the bit line connection region 103a may correspond to a common drain region, and the storage connection region 103b may correspond to a source region. Each word line WL, and the bit line connection region 103a and the storage connection region 103b, which are adjacent to the word line WL, may constitute a transistor.

A plurality of bit lines BL extended in a second direction DR2 orthogonal to the word line WL may be disposed on the word line WL. The plurality of bit lines BL may be extended in parallel with each other. The bit lines BL may be disposed at constant intervals. A width of the bit line BL or an interval between the bit lines BL may be determined in accordance with the design rule.

A fourth direction DR4 may be orthogonal to the first direction DR1, the second direction DR2 and the third direction DR3. The fourth direction DR4 may be a thickness direction of the substrate 100.

The semiconductor memory device according to some embodiments may include various contact arrangements formed on the cell active region ACT. The various contact arrangements may include, for example, a direct contact DC, a node pad XP, a landing pad LP, and the like.

In this case, the direct contact DC may refer to a contact that electrically connects the cell active region ACT to the bit line BL. The node pad XP may be a connection pad that connects the cell active region ACT to a lower electrode (191 of FIG. 8) of the first capacitor structure. A contact area between the node pad XP and the cell active region ACT may be small in view of an arrangement structure of the semiconductor memory device. Therefore, a conductive landing pad LP may be introduced to enlarge the contact area with the lower electrode (191 of FIG. 8) of the first capacitor structure while enlarging the contact area with the cell active region ACT.

The landing pad LP may be disposed between the node pad XP and the lower electrode (191 of FIG. 8) of the first capacitor structure. As the contact area is enlarged through the introduction of the landing pad LP, contact resistance between the cell active region ACT and the lower electrode 191 of the capacitor may be reduced.

The direct contact DC may be connected to the bit line connection region 103a. The node pad XP may be connected to the storage connection region 103b.

As the node pad XP is disposed at both end portions of the cell active region ACT, the landing pad LP may be disposed to partially overlap the node pad XP in a state that it is adjacent to both ends of the cell active region ACT. In other words, the node pad XP may be formed to overlap the cell active region ACT and the cell element isolation film (105 of FIG. 8) between adjacent word lines WL and between adjacent bit lines BL.

The word line WL may be formed in a structure buried in the second substrate (100 of FIG. 8). The word line WL may be disposed across the cell active region ACT between the direct contacts DC or the node pads XP. As shown, two word lines WL may be disposed to cross any one cell active region ACT. As the cell active region ACT is extended along the third direction DR3, the word line WL may have an angle less than 90° with the cell active region ACT.

The direct contact DC and the node pad XP may be symmetrically disposed. For example, the direct contact DC and the node pad XP may be arranged in an array in the first direction DR1 and the second direction DR2. For this reason, the direct contact DC and the node pad XP may be disposed on a straight line along the first direction DR1 and the second direction DR2. Unlike the direct contact DC and the node pad XP, the landing pad LP may be disposed in a zigzag shape in the second direction DR2 in which the bit line BL is extended. In addition, the landing pad LP may be disposed to overlap the same side portion of each bit line BL in the first direction DR1 in which the word line WL is extended.

For example, each landing pad LP of a first line extending in the first direction DR1 may overlap a left side of a corresponding bit line BL, and each landing pad LP of a second line extending in the first direction DR1 may overlap a right side of a corresponding bit line BL.

Referring to FIGS. 8 and 9, the semiconductor memory device according to some embodiments may include a plurality of cell gate structures 110, a plurality of bit line structures 140ST, a plurality of node connection pads 125, a plurality of bit line contacts 146, and a first capacitor structure 190.

The second substrate 100 may be a silicon substrate or a silicon-on-insulator (SOI). Alternatively, the second substrate 100 may include, but is not limited to, silicon germanium, silicon germanium on insulator (SGOI), indium antimonide, lead telluride compound, indium arsenide, indium phosphide, gallium arsenide or gallium antimonide.

The cell element isolation film 105 may be formed in the second substrate 100. The cell element isolation film 105 may have a shallow trench isolation (STI) structure having excellent element isolation characteristics. The cell element isolation film 105 may define the cell active region ACT in a memory cell region.

The cell active region ACT defined by the cell element isolation film 105 may have a long island shape including a short axis and a long axis as shown in FIGS. 6 and 7. The cell active region ACT may have an oblique shape so as to have an angle less than 90° with respect to the word line WL formed in the cell element isolation film 105. In addition, the cell active region ACT may have an oblique shape so as to have an angle less than 90° with respect to the bit line BL formed on the cell element isolation film 105.

The cell element isolation film 105 may be or include, but is not limited to, at least one of, for example, a silicon oxide film, a silicon nitride film or a silicon oxynitride film.

The cell element isolation film 105 is shown as being formed of one insulating film, but this is only for convenience of description and the inventive concept is not limited thereto. The cell element isolation film 105 may be formed of one insulating film or a plurality of insulating films depending on a distance at which the adjacent cell active regions ACT are spaced apart from each other.

Although an upper surface 105US of the cell element isolation film 105 and an upper surface of the second substrate 100 are shown as being disposed on the same plane, it is only for convenience of description and the present disclosure is not limited thereto.

The cell gate structure 110 may be formed in the second substrate 100 and the cell element isolation film 105. The cell gate structure 110 may be formed across the cell element isolation film 105 and the cell active region ACT defined by the cell element isolation film 105.

The cell gate structure 110 is formed in the second substrate 100 and the cell element isolation film 105. The cell gate structure 110 may include a cell gate trench 115, a cell gate insulating film 111, a cell gate electrode 112, a cell gate capping pattern 113 and a cell gate capping conductive film 114.

In this case, the cell gate electrode 112 may correspond to the word line WL. For example, the cell gate electrode 112 may be the word line WL of FIGS. 6 and 7. Unlike the shown example, the cell gate structure 110 may not include the cell gate capping conductive film 114.

Although not shown, the cell gate trench 115 may be relatively deep in the cell element isolation film 105, and may be relatively shallow in the cell active regions ACT. A bottom surface of the word line WL may be curved. That is, a depth of the cell gate trench 115 in the cell element isolation film 105 may be greater than that of the cell gate trench 115 in the cell active region ACT.

The cell gate insulating film 111 may be extended along sidewalls and a bottom surface of the cell gate trench 115. The cell gate insulating film 111 may be extended along a profile of at least a portion of the cell gate trench 115.

The cell gate insulating film 111 may be or include at least one of, for example, silicon oxide, silicon nitride, silicon oxynitride or a high-k material having a dielectric constant higher than that of silicon oxide. The high-k material may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate or their combination.

The cell gate electrode 112 may be formed on the cell gate insulating film 111. The cell gate electrode 112 may fill a portion of the cell gate trench 115. The cell gate capping conductive film 114 may be extended along an upper surface of the cell gate electrode 112.

The cell gate electrode 112 may include at least one of a metal, a metal alloy, a conductive metal nitride, a conductive metal carbonitride, a conductive metal carbide, a conductive metal silicide, a doped semiconductor material, a conductive metal oxynitride or a conductive metal oxide. The cell gate electrode 112 may include at least one of, for example, TiN, TaC, TaN, TiSiN, TaSiN, TaTiN, TiAlN, TaAlN, WN, Ru, TiAl, TiAlC-N, TiAlC, TiC, TaCN, W, Al, Cu, Co, Ti, Ta, Ni, Pt, Ni-Pt, Nb, NbN, NbC, Mo, MoN, MoC, WC, Rh, Pd, Ir, Ag, Au, Zn, V, RuTiN, TiSi, TaSi, NiSi, CoSi, IrO, RuO or their combination, but is not limited thereto.

The cell gate capping conductive film 114 may include one of, for example, polysilicon, polysilicon-germanium, amorphous silicon, and amorphous silicon-germanium, but is not limited thereto.

The cell gate capping pattern 113 may be disposed on the cell gate electrode 112 and the cell gate capping conductive film 114. The cell gate capping pattern 113 may fill the portion of the cell gate trench 115 remaining after the cell gate electrode 112 and the cell gate capping conductive film 114 are formed. The cell gate insulating film 111 is shown as being extended along sidewalls of the cell gate capping pattern 113, but is not limited thereto.

The cell gate capping pattern 113 may be or include at least one of, for example, silicon nitride, silicon oxynitride, silicon oxide, silicon carbonitride, silicon oxycarbonitride or their combination.

An upper surface 113US of the cell gate capping pattern 113 is shown as being disposed on the same plane as the upper surface 105US of the cell element isolation film 105, but is not limited thereto.

Although not shown, an impurity doping region may be formed on at least one side of the cell gate structure 110. The impurity doping region may be a source/drain region of a transistor. The impurity doping region may correspond to the storage connection region 103b and the bit line connection region 103a of FIG. 7.

In FIG. 7, when a transistor, which includes each word line WL, and the bit line connection region 103a and the storage connection region 103b, which are adjacent to each word line WL, is an NMOS transistor, the storage connection region 103b and the bit line connection region 103a may include at least one of doped n-type impurities, for example, phosphorus (P), arsenic (As), antimony (Sb) or bismuth (Bi). When the transistor, which includes each word line WL, and the bit line connection region 103a and the storage connection region 103b, which are adjacent to each word line WL, is a PMOS transistor, the storage connection region 103b and the bit line connection region 103a may include doped P-type impurities, for example, at least one of boron (B) or gallium (Ga).

The bit line structure 140ST may include a cell conductive line 140 and a cell line capping film 144. The cell conductive line 140 may be disposed on the substrate 100, on which the cell gate structure 110 is formed, and the cell element isolation film 105. The cell conductive line 140 may cross the cell element isolation film 105 and the cell active region ACT defined by the cell element isolation film 105. The cell conductive line 140 may be formed to cross the cell gate structure 110. In this case, the cell conductive line 140 may correspond to the bit line BL. For example, the cell conductive line 140 may be the bit line BL of FIG. 6.

The cell conductive line 140 may be or include at least one of, for example, a semiconductor material doped with impurities, a conductive metal silicide, a conductive metal nitride, a two-dimensional (2D) material, a metal or a metal alloy. In the semiconductor memory device according to some embodiments, the two-dimensional material may be a metallic material and/or a semiconductor material. The two-dimensional (2D) material may include a two-dimensional allotrope or a two-dimensional compound, and may include at least one of, for example, graphene, molybdenum disulfide (MoS₂), molybdenum diselenide (MoSe₂), tungsten diselenide (WSe₂) or tungsten disulfide (WS₂), but is not limited thereto. That is, since the two-dimensional materials described above are only examples, the two-dimensional material that may be included in the semiconductor memory device of the present disclosure is not limited by the above-described materials.

The cell conductive line 140 is shown as a single film, but it is only for convenience of description and is not limited thereto. That is, unlike the shown example, the cell conductive line 140 may include a plurality of conductive films in which conductive materials are stacked.

The cell line capping film 144 may be disposed on the cell conductive line 140. The cell line capping film 144 may be extended in the second direction DR2 along an upper surface of the cell conductive line 140. The cell line capping film 144 may be or include at least one of, for example, silicon nitride, silicon oxynitride, silicon carbonitride or silicon oxycarbonitride.

In the semiconductor memory device according to some embodiments, the cell line capping film 144 may include a silicon nitride film. The cell line capping film 144 is shown as a single film, but is not limited thereto.

The bit line contact 146 may be formed between the cell conductive line 140 and the second substrate 100. The cell conductive line 140 may be disposed on the bit line contact 146.

The bit line contact 146 may be formed between the cell conductive line 140 and the second substrate 100. The cell conductive line 140 may be disposed on the bit line contact 146. The bit line contact 146 may be formed between the bit line connection region 103a of the cell active region ACT and the cell conductive line 140 (see, e.g., FIG. 9). The bit line contact 146 may be connected with the bit line connection region 103a.

In a plan view, the bit line contact 146 may have a circular or elliptical shape. A planar area of the bit line contact 146 may be greater than an area in which the bit line connection region 103a overlaps one cell conductive line 140. The planar area of the bit line contact 146 may be greater than a planar area of one bit line connection region 103a.

The bit line contact 146 may include an upper surface 146US connected to the cell conductive line 140. A width of the bit line contact 146 in the first direction DR1 is shown as being constant with distance from the upper surface 146US of the bit line contact 146, but this is only for convenience of description, and the inventive concept is not limited thereto.

The bit line contact 146 may electrically connect the cell conductive line 140 with the second substrate 100. In this case, the bit line contact 146 may correspond to the direct contact DC. The bit line contact 146 may be or include at least one of, for example, a semiconductor material doped with impurities, a conductive metal silicide, a conductive metal nitride, a conductive metal oxide, a metal or a metal alloy.

The node connection pad 125 may be disposed on the second substrate 100. The node connection pad 125 may be disposed on the storage connection region 103b of the cell active region ACT. The node connection pad 125 is connected with the storage connection region 103b.

The node connection pad 125 may be disposed between the cell conductive lines 140 adjacent to each other in the first direction DR1. Although not shown, the node connection pad 125 may be disposed between the cell gate electrodes 112 adjacent to each other in the second direction DR2.

An upper surface 125US of the node connection pad is lower than the upper surface 146US of the bit line contact based on the upper surface 105US of the cell element isolation film. The upper surface 125US of the node connection pad is lower than a bottom surface of the cell conductive line 140 based on the upper surface 105US of the cell element isolation film.

The node connection pad 125 may electrically connect the second capacitor structure 190 with the second substrate 100. In this case, the node connection pad 125 may correspond to the node pad XP.

The node connection pad 125 may be or include at least one of, for example, a semiconductor material doped with impurities, a conductive metal silicide, a conductive metal nitride, a conductive metal oxide, a metal or a metal alloy.

A pad isolation structure 145ST may space the node connection pads 125 adjacent to each other in the first direction DR1 apart from each other. Although not shown, the pad isolation structure 145ST may space the node connection pads 125 adjacent to each other in the second direction DR2 apart from each other. The pad isolation structure 145ST covers the upper surface 125US of the node connection pad.

The pad isolation structure 145ST may include a pad isolation pattern 145 and an upper cell insulating film 130. The upper cell insulating film 130 may be disposed on the pad isolation pattern 145.

When the node connection pad 125 includes a first node connection pad and a second node connection pad, which are spaced apart from each other in the first direction DR1, the pad isolation pattern 145 may space the first node connection pad and the second node connection pad apart from each other in the first direction DR1. Although not shown, the pad isolation pattern 145 may also space the node connection pads 125 adjacent to each other in the second direction DR2 apart from each other.

The upper cell insulating film 130 covers the upper surface 125US of the node connection pad. When the node connection pad 125 includes a first node connection pad and a second node connection pad, which are spaced apart from each other in the first direction DR1, the upper cell insulating film 130 may cover an upper surface of the first node connection pad and an upper surface of the second node connection pad.

An upper surface 130US of the upper cell insulating film may be disposed on the same plane as the upper surface 146US of the bit line contact. That is, a height of the upper surface 130US of the upper cell insulating film may be the same as that of the upper surface 146US of the bit line contact based on the upper surface 105US of the cell element isolation film.

The pad isolation pattern 145 and the upper cell insulating film 130 may be disposed between the bit line contacts 146 adjacent to each other in the second direction DR2. The cell conductive line 140 may be disposed on an upper surface of the pad isolation structure 145ST. The cell conductive line 140 may be disposed on the upper surface 130US of the upper cell insulating film. The upper surface of the pad isolation structure 145ST may be the upper surface 130US of the upper cell insulating film. The upper surface of the pad isolation structure 145ST may be disposed on the bottom surface of the cell conductive line 140.

In FIG. 9, a bit line contact spacer 146SP may be disposed between the bit line contact 146 and the pad isolation pattern 145. The bit line contact spacer 146SP may be disposed along sidewalls of the bit line contact 146. The bit line contact spacers 146SP disposed on the sidewalls of the bit line contact 146 are spaced apart from each other in the second direction DR2.

The bit line contact spacer 146SP may be or include at least one of, for example, silicon nitride (SiN), silicon oxynitride (SiON) or silicon oxide (SiO₂). Although the bit line contact spacer 146SP is shown as a single film, it is only for convenience of description and the present disclosure is not limited thereto. Unlike the shown example, the bit line contact spacer 146SP may not be formed.

The pad isolation pattern 145 may be or include at least one of, for example, silicon nitride (SiN), silicon oxynitride (SiON), silicon oxide (SiO₂), silicon carbonitride (SiCN), silicon oxycarbonitride (SiOCN) or their combination. The upper cell insulating film 130 may be a single film, but may be a multi-film that includes a first upper cell insulating film 131 and a second upper cell insulating film 132 as shown. For example, the first upper cell insulating film 131 may be or include a silicon oxide film, and the second upper cell insulating film 132 may be or include a silicon nitride film, but the present disclosure is not limited thereto. A width of the upper cell insulating film 130 in the first direction DR1 is shown as being reduced with distance from the second substrate 100, but is not limited thereto.

The bit line spacer 150 may be disposed on sidewalls of the cell conductive line 140 and the cell line capping film 144.

In a portion of the cell conductive line 140, in which the bit line contact 146 is formed, the bit line spacer 150 may be disposed on sidewalls of the cell conductive line 140, the cell line capping film 144 and the bit line contact 146. In the other portion of the cell conductive line 140, in which the bit line contact 146 is not formed, the bit line spacer 150 may be disposed on the upper cell insulating film 130.

The bit line spacer 150 is shown as a single film, but it is only for convenience of description and is not limited thereto. That is, unlike the shown example, the bit line spacer 150 may have a multi-layered structure. The bit line spacer 150 may be or include one of, for example, a silicon oxide film, a silicon nitride film, a silicon oxynitride (SiON) layer, a silicon oxycarbonitride (SiOCN) layer, air and their combination, but is not limited thereto.

The storage pad 160 may be disposed on each node connection pad 125. The storage pad 160 may be electrically connected to the node connection pad 125. The storage pad 160 may be connected to the storage connection region 103b of the cell active region ACT. In this case, the storage pad 160 may correspond to the landing pad LP.

In the semiconductor memory device according to some embodiments, the storage pad 160 may be extended to the node connection pad 125 and thus connected to the node connection pad 125. The storage pad 160 may overlap a portion of the upper surface of the bit line structure 140ST when viewed in plan view.

The storage pad 160 may be or include at least one of, for example, a semiconductor material doped with impurities, a conductive metal silicide, a conductive metal nitride, a conductive metal carbide, a conductive metal oxide, a metal or a metal alloy.

The pad isolation insulating film 180 may be formed on the storage pad 160 and the bit line structure 140ST. For example, the pad isolation insulating film 180 may be disposed on the cell line capping film 144. The pad isolation insulating film 180 may define the storage pad 160 that forms a plurality of isolation regions.

The pad isolation insulating film 180 does not cover an upper surface 160US of the storage pad 160. The pad isolation insulating film 180 may fill a pad isolation recess. The pad isolation recess may isolate adjacent storage pads 160 from each other. For example, the upper surface 160US of the storage pad 160 may be disposed on the same plane as the upper surface 180US of the pad isolation insulating film.

The pad isolation insulating film 180 may include an insulating material and electrically separate the plurality of storage pads 160 from each other. For example, the pad isolation insulating film 180 may be or include at least one of, for example, a silicon oxide film, a silicon nitride film, a silicon oxynitride film, a silicon oxycarbonitride film or a silicon carbonitride film, but is not limited thereto.

A first etch stop film 195 may be disposed on the storage pad 160 and the pad isolation insulating film 180. The first etch stop film 195 may be or include at least one of a silicon nitride film, a silicon carbonitride film, a silicon boron nitride film (SiBN), a silicon oxynitride film or a silicon oxycarbide film.

The first capacitor structure 190 may be disposed on the storage pad 160. The first capacitor structure 190 may be electrically connected to the storage pad 160. A portion of the first capacitor structure 190 may be disposed in the first etch stop film 195.

The first capacitor structure 190 may include a first lower electrode 191, a first capacitor dielectric film 192, an interface blocking film 35, and a first upper electrode 193.

The first lower electrode 191 may be connected to the storage pad 160. For example, the first lower electrode 191 may be in contact with a portion of the upper surface 160US of the storage pad 160, which is exposed by the first etch stop film 195. In FIG. 8, the first lower electrode 191 is shown as being in the form of a pillar extended in the fourth direction DR4 from the upper surface 160US of the storage pad 160, but this is only an example. For another example, the first lower electrode 191 may be in the form of a cylinder extended in the fourth direction DR4 from the upper surface 160US of the storage pad 160.

The first capacitor dielectric film 192 may be formed on the first lower electrode 191. In some embodiments, the first capacitor dielectric film 192 may be extended along a profile of sides and an upper surface of the first lower electrode 191.

The interface blocking film 35 may be disposed between the first lower electrode 191 and the first capacitor dielectric film 192. The interface blocking film 35 may be extended along a profile of sides and an upper surface of the first lower electrode 191.

The first upper electrode 193 may be formed on the first capacitor dielectric film 192. In FIG. 8, the first upper electrode 193 is shown as only filling a region between adjacent first lower electrodes 191, but this is only an example. As another example, the first upper electrode 193 may be extended along the profile of the first capacitor dielectric film 192.

The first lower electrode 191, the first capacitor dielectric film 192 and the first upper electrode 193 may respectively correspond to the lower electrode 30, the capacitor dielectric film 40 and the upper electrode 50, respectively, which are described above with reference to FIGS. 1 to 5. For example, as shown in FIG. 10, the first lower electrode 191 may include a lower electrode film 31, a lower insertion electrode film 32 and a lower interface electrode film 33, which are sequentially stacked. Therefore, a detailed description of the lower electrode film 31, the lower insertion electrode film 32 and the lower interface electrode film 33 will be omitted below. The interface blocking film 35 included in the first capacitor structure 190 may correspond to the interface blocking film 35 described above with reference to FIGS. 1 to 5.

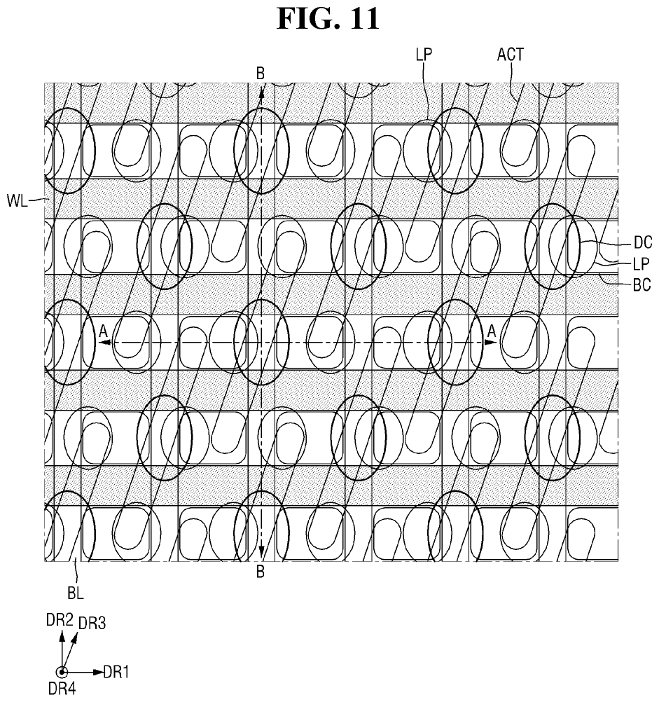

FIGS. 11 to 13 are views illustrating a semiconductor memory device according to some embodiments. For convenience of description, the following description will be based on differences from the description made with reference to FIGS. 6 to 10.

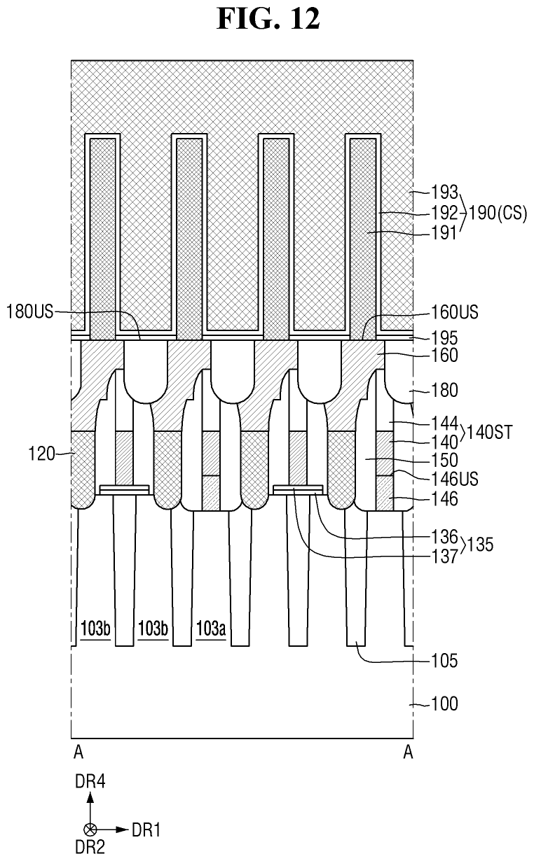

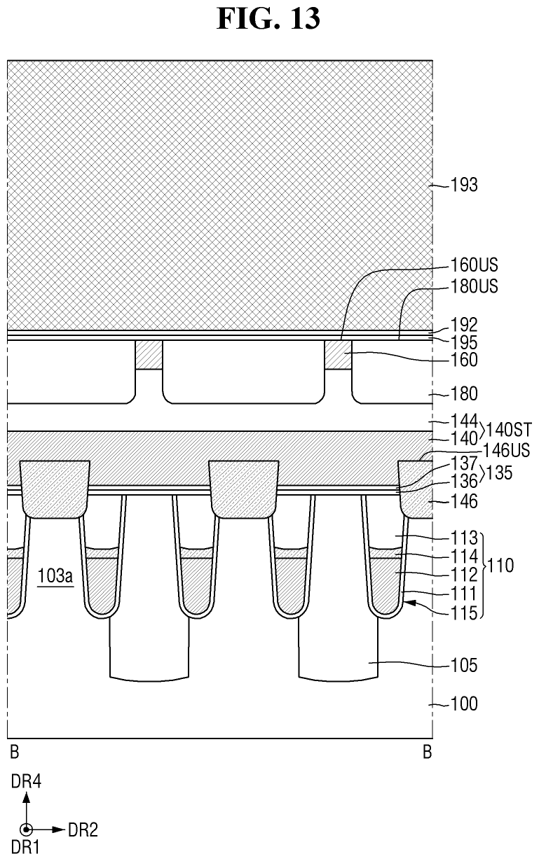

For reference, FIG. 11 is a schematic layout of a semiconductor memory device according to some embodiments. FIGS. 12 and 13 are cross-sectional views taken along lines A-A and B-B of FIG. 11.

Referring to FIGS. 11 to 13, the semiconductor memory device according to some embodiments includes a buried contact BC for connecting the cell active region ACT to the lower electrode 191, and does not include the node pad (XP of FIG. 6).

The landing pad LP may be disposed between the buried contact BC and the first lower electrode 191.

The lower cell insulating film 135 may be formed on the second substrate 100 and the cell element isolation film 105. In more detail, the lower cell insulating film 135 may be disposed on portions of the cell element isolation film 105 and the second substrate 100 on which the bit line contact 146 is not formed. The lower cell insulating film 135 may be disposed between the second substrate 100 and the cell conductive line 140 and between the cell element isolation film 105 and the cell conductive line 140.

The lower cell insulating film 135 may be a single film, but may be a multi-film that includes a first lower cell insulating film 136 and a second lower cell insulating film 137 as shown. For example, the first lower cell insulating film 136 may include a silicon oxide film, and the second lower cell insulating film 137 may include a silicon nitride film, but the present disclosure is not limited thereto. Unlike the shown example, the lower cell insulating film 137 may include three or more insulating films.

A portion of the bit line contact 146 may be recessed into the cell conductive line 140 (see, e.g., FIG. 13). The upper surface 146US of the bit line contact may be higher than the upper surface of the lower cell insulating film 135. A height of the upper surface 146US of the bit line contact is higher than that of the upper surface of the lower cell insulating film 135.

The plurality of storage contacts 120 may be disposed between the cell conductive lines 140 adjacent to each other in the first direction DR1. The storage contact 120 may overlap the substrate 100 and the cell element isolation film 105 between the adjacent cell conductive lines 140. The storage contact 120 may be connected to the storage connection region (103b of FIG. 7) of the cell active region ACT. In this case, the storage contact 120 may correspond to the buried contact BC.

The plurality of storage contacts 120 may be or include at least one of, for example, a semiconductor material doped with impurities, a conductive metal silicide, a conductive metal nitride, a conductive metal carbide, a conductive metal carbonitride, a conductive metal oxide, a metal or a metal alloy.

The storage pad 160 may be disposed on the storage contact 120. The storage pad 160 may be electrically connected to the storage contact 120.

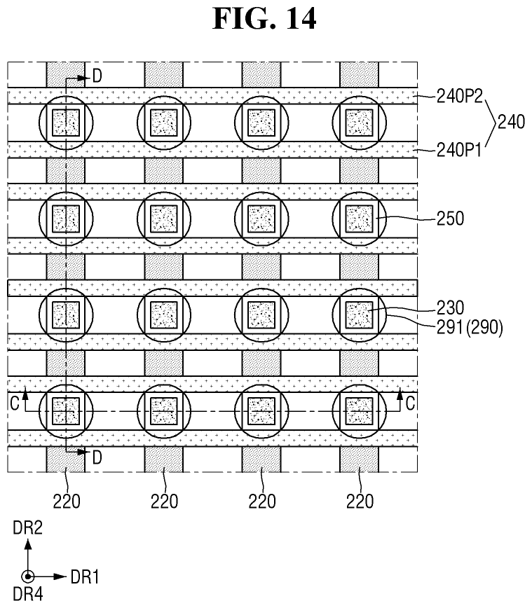

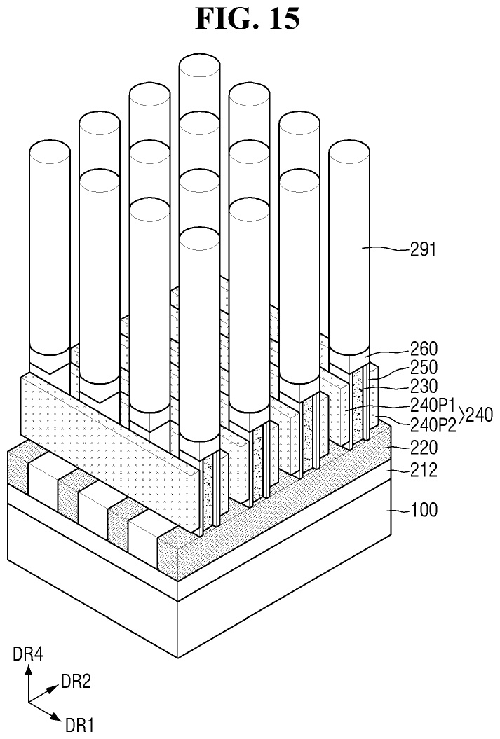

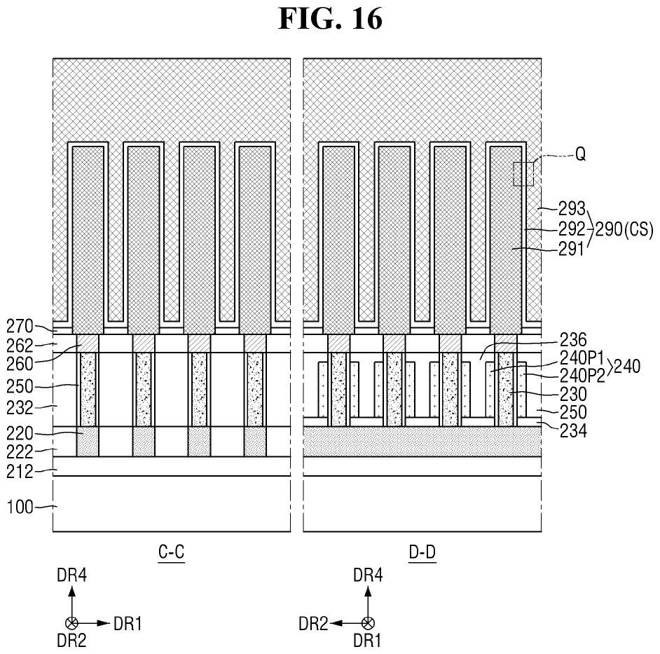

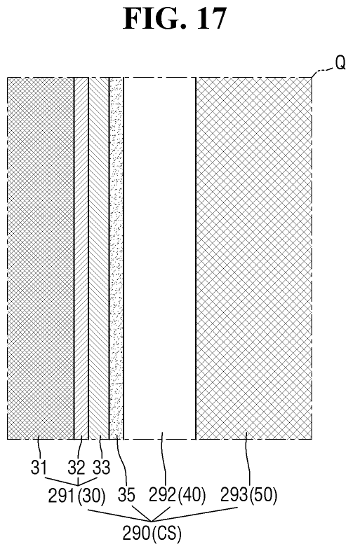

FIG. 14 is a layout view illustrating a semiconductor memory device according to some embodiments. FIG. 15 is a perspective view illustrating a semiconductor memory device according to some embodiments. FIG. 16 is a cross-sectional view taken along lines C-C and D-D of FIG. 14. FIG. 17 is an enlarged view illustrating a region Q of FIG. 16.

Referring to FIGS. 14 to 17, the semiconductor memory device according to some embodiments may include a second substrate 100, a plurality of first conductive lines 220, a channel layer 230, a gate electrode 240, a gate insulating film 250, and a second capacitor structure 290. The semiconductor memory device according to some embodiments may be a memory device that includes a vertical channel transistor (VCT). The vertical channel transistor may indicate a structure in which a channel length of the channel layer 230 is extended along a vertical direction from the second substrate 100.

The first lower insulating film 212 may be disposed on the second substrate 100. The plurality of first conductive lines 220 may be spaced apart from each other in the first direction DR1 on the first lower insulating film 212 and extended in the second direction DR2. A plurality of first insulating patterns 222 may be disposed on the first lower insulating film 212 to fill spaces between adjacent ones of the plurality of first conductive lines 220. The plurality of first insulating patterns 222 may be extended in the second direction DR2. An upper surface of the plurality of first insulating patterns 222 may be disposed at the same level as an upper surface of the plurality of first conductive lines 220. The plurality of first conductive lines 220 may serve as bit lines.

The plurality of first conductive lines 220 may be or include a doped semiconductor material, a metal, a metal alloy, a conductive metal nitride, a conductive metal silicide, a conductive metal oxide or their combination. For example, the plurality of first conductive lines 220 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO or their combination, but is not limited thereto. The plurality of first conductive lines 220 may include a single layer or multi-layer of the aforementioned materials. In example embodiments, the plurality of first conductive lines 220 may include graphene, a carbon nanotube or their combination.

The channel layers 230 may be arranged in the form of a matrix in which they are disposed to be spaced apart from each other in the first direction DR1 and the second direction DR2 on the plurality of first conductive lines 220. The channel layer 230 may have a first width in the first direction DR1 and a first height in the fourth direction DR4, wherein the first height may be greater than the first width. In this case, the fourth direction DR4 may be, for example, a direction perpendicular to the upper surface of the second substrate 100. For example, the first height may be about 2 to 10 times the first width, but is not limited thereto. A bottom portion of the channel layer 230 may serve as a first source/drain region (not shown), an upper portion of the channel layer 230 may serve as a second source/drain region (not shown), and a portion of the channel layer 230 between the first and second source/drain regions may serve as a channel region (not shown).

In example embodiments, the channel layer 230 may be or include an oxide semiconductor, and for example, the oxide semiconductor may include InGaZnO, InGaSiO, InSnZnO, InZnO, ZnO, ZnSnO, ZnON, ZrZnSnO, SnO, HfInZnO, GaZnSnO, AlZnSnO, YbGaZnO, InGaO or their combination. The channel layer 230 may include a single layer or multi-layer of the oxide semiconductor. In some examples, the channel layer 230 may have a bandgap energy that is greater than a bandgap energy of silicon. For example, the channel layer 230 may have a bandgap energy of about 1.5 eV to 5.6 eV. For example, the channel layer 230 may have optimal channel performance when having a bandgap energy of about 2.0 eV to 4.0 eV For example, the channel layer 230 may be polycrystalline or amorphous, but is not limited thereto. In example embodiments, the channel layer 230 may include graphene, a carbon nanotube or their combination.

The gate electrode 240 may be extended in the first direction DR1 on both sidewalls of the channel layer 230. The gate electrode 240 may include a first sub-gate electrode 240P1 facing a first sidewall of the channel layer 230 and a second sub-gate electrode 240P2 facing a second sidewall opposite to the first sidewall of the channel layer 230. As one channel layer 230 is disposed between the first sub-gate electrode 240P1 and the second sub-gate electrode 240P2, the semiconductor device may have a dual gate transistor structure, but the technical spirit of the present disclosure is not limited thereto. The second sub-gate electrode 240P2 may be omitted, and only the first sub-gate electrode 240P1 facing the first sidewall of the channel layer 230 may be formed to implement a single gate transistor structure. The material included in the gate electrode 240 may be the same as that in the description of the cell gate electrode 112.

The gate insulating film 250 may surround the sidewalls of the channel layer 230, and may be interposed between the channel layer 230 and the gate electrode 240. For example, as shown in FIG. 14, the entire sidewalls of the channel layer 230 may be surrounded by the gate insulating film 250, and a portion of the sidewalls of the gate electrode 240 may be in contact with the gate insulating film 250. In other embodiments, the gate insulating film 250 may be extended in the direction (i.e., the first direction DR1) in which the gate electrode 240 is extended, and only two sidewalls facing the gate electrode 240 among the sidewalls of the channel layer 230 may be in contact with the gate insulating film 250. In example embodiments, the gate insulating film 250 may be or include a silicon oxide film, a silicon oxynitride film, a high-k dielectric material having a dielectric constant higher than that of the silicon oxide film or their combination.

The plurality of second insulating patterns 232 may be extended along the second direction DR2 on the plurality of first insulating patterns 222. The channel layer 230 may be disposed between two adjacent second insulating patterns 232 among the plurality of second insulating patterns 232. In addition, between two adjacent second insulating patterns 232, a first buried layer 234 and a second buried layer 236 may be disposed in a space between two adjacent channel layers 230. The first buried layer 234 may be disposed on a bottom portion of the space between two adjacent channel layers 230. The second buried layer 236 may be formed on the first buried layer 234 to fill the remainder of the space between the two adjacent channel layers 230. An upper surface of the second buried layer 236 may be disposed at the same level as an upper surface of the channel layer 230, and the second buried layer 236 may cover the upper surface of the gate electrode 240. Alternatively, the plurality of second insulating patterns 232 may be formed of a material layer continuous with the plurality of first insulating patterns 222, or the second buried layer 236 may be formed of a material layer continuous with the first buried layer 234.

The capacitor contact 260 may be disposed on the channel layer 230. The capacitor contacts 260 may be disposed to vertically overlap the channel layer 230, and may be arranged in the form of a matrix in which they are spaced apart from each other in the first direction DR1 and the second direction DR2. The capacitor contact 260 may be made of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrO, RuO or their combination, but is not limited thereto. The upper insulating film 262 may surround sidewalls of the capacitor contact 260 on the plurality of second insulating patterns 232 and the second buried layer 236.

A second etch stop film 270 may be disposed on the upper insulating film 262. The second capacitor structure 290 may be disposed on the second etch stop film 270. The second capacitor structure 290 may include a second lower electrode 291, a second capacitor dielectric film 292, an interface blocking film 35, and a second upper electrode 293. The second lower electrode 291 may be electrically connected to an upper surface of the capacitor contact 260 by passing through the second etch stop film 270. The second lower electrode 291 may be formed in a shape of a pillar extended in the fourth direction DR4, but is not limited thereto. In example embodiments, the second lower electrodes 291 may be disposed to vertically overlap the capacitor contact 260, and may be arranged in the form of a matrix in which they are spaced apart from each other in the first direction DR1 and the second direction DR2. Alternatively, a landing pad (not shown) may be further disposed between the capacitor contact 260 and the second lower electrode 291, so that the second lower electrode 291 may be arranged in a hexagonal shape.

The second capacitor dielectric film 292 may be formed on the second lower electrode 291. In some embodiments, the second capacitor dielectric film 292 may be extended along a profile of sides and an upper surface of the second lower electrode 191.

The interface blocking film 35 may be disposed between the second lower electrode 291 and the second capacitor dielectric film 292. The interface blocking film 35 may be extended along a profile of sides and an upper surface of the second lower electrode 291.

The second upper electrode 293 may be formed on the second capacitor dielectric film 292. The second upper electrode 293 may fill a region between adjacent second lower electrodes 291, but this is only an example. As another example, the second upper electrode 293 may be extended along the profile of the second capacitor dielectric film 292.

The second lower electrode 291, the second capacitor dielectric film 292 and the second upper electrode 293 may respectively correspond to the lower electrode 30, the capacitor dielectric film 40 and the upper electrode 50, which are described above with reference to FIGS. 1 to 5. For example, as shown in FIG. 17, the second lower electrode 291 may include a lower electrode film 31, a lower insertion electrode film 32 and a lower interface electrode film 33, which are sequentially stacked. The interface blocking film 35 included in the second capacitor structure 290 may correspond to the interface blocking film 35 described above with reference to FIGS. 1 to 5.

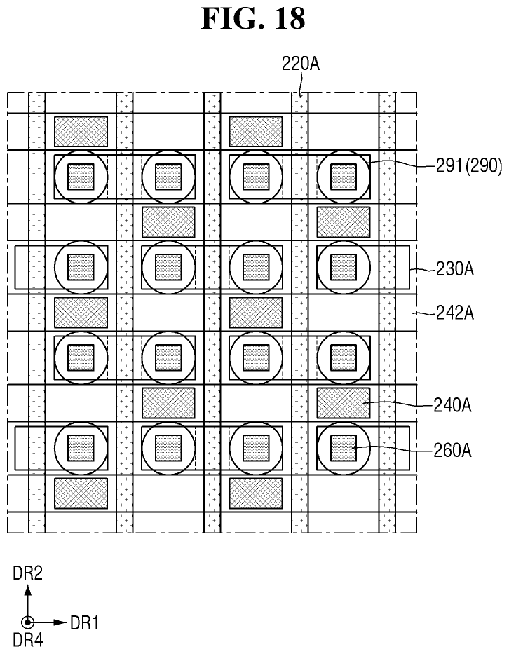

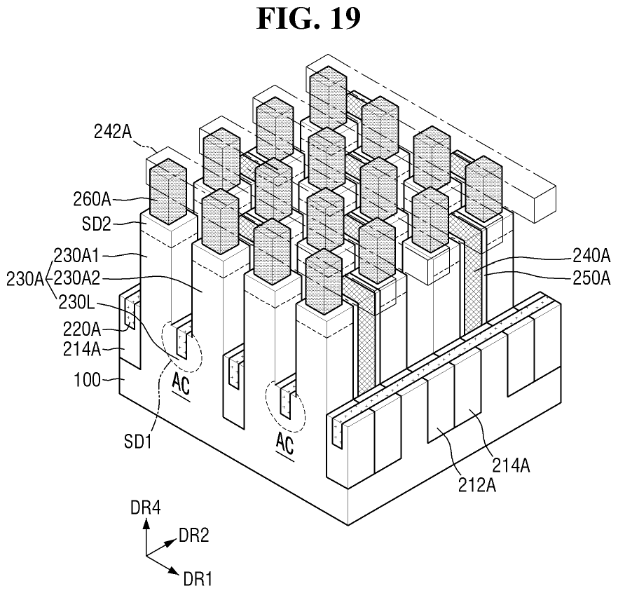

FIG. 18 is a layout view illustrating a semiconductor memory device according to some embodiments. FIG. 19 is a perspective view illustrating a semiconductor memory device according to some embodiments.

Referring to FIGS. 18 and 19, the semiconductor memory device according to some embodiments may include a second substrate 100, a plurality of first conductive lines 220A, a channel structure 230A, a contact gate electrode 240A, a plurality of second conductive lines 242A, and a second capacitor structure 290. The semiconductor memory device according to some embodiments may be a memory device that includes a vertical channel transistor (VCT).

A plurality of active regions AC may be defined on the second substrate 100 by a first element isolation pattern 212A and a second element isolation pattern 214A. The channel structure 230A may be disposed inside each active region AC. The channel structures 230A may include a first active pillar 230A1 and a second active pillar 230A2, which are extended in the vertical direction, and a connection portion 230L connected to a bottom portion of the first active pillar 230A1 and a bottom portion of the second active pillar 230A2. A third source/drain region SD1 may be disposed in the connection portion 230L. A fourth source/drain region SD2 may be disposed above the first and second active pillars 230A1 and 230A2. Each of the first active pillar 230A1 and the second active pillar 230A2 may constitute an independent unit memory cell.

The plurality of first conductive lines 220A may be extended in a direction crossing each of the plurality of active regions AC, and may be extended in the second direction DR2, for example. One of the plurality of first conductive lines 220A may be disposed on the connection portion 230L between the first active pillar 230A1 and the second active pillar 230A2. One of the first conductive lines 220A may be disposed on the third source/drain region SD1. Another first conductive line 220A adjacent to one of the first conductive lines 220A may be disposed between two channel structures 230A. One of the plurality of first conductive lines 220A may serve as a common bit line included in two unit memory cells constituted by the first active pillar 230A1 and the second active pillar 230A2, which are disposed on both sides of one first conductive line 220A.

One contact gate electrode 240A may be disposed between two channel structures 230A adjacent to each other in the second direction DR2. For example, the contact gate electrode 240A may be disposed between the first active pillar 230A1 included in one channel structure 230A and the second active pillar 230A2 of the channel structure 230A adjacent thereto. One contact gate electrode 240A may be shared by the first active pillar 230A1 and the second active pillar 230A2, which are respectively disposed on two opposite sidewalls thereof. A fourth gate insulating film 250A may be disposed between the contact gate electrode 240A and the first active pillar 230A1 and between the contact gate electrode 240A and the second active pillar 230A2. The plurality of second conductive lines 242A may be extended in the first direction DR1 on an upper surface of the contact gate electrode 240A. The plurality of second conductive lines 242A may serve as word lines of the semiconductor memory device.

A capacitor contact 260A may be disposed on the channel structure 230A. The capacitor contact 260A may be disposed on the fourth source/drain region SD2, and the second capacitor structure 290 (see, e.g., FIG. 18) may be disposed on the capacitor contact 260A.

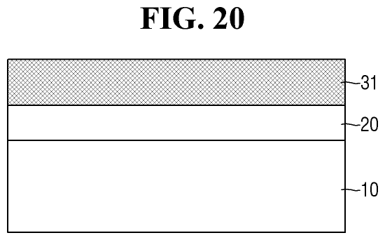

FIGS. 20 to 23 are views illustrating intermediate steps to describe a method for fabricating a capacitor structure according to some embodiments. For convenience of description, redundant portions of those described with reference to FIGS. 1 to 5 will be briefly described or omitted.

Referring to FIG. 20, the lower insulating film 20 and the lower electrode film 31 may be formed on the substrate 10.

The lower insulating film 20 may be formed on the substrate 10. The lower insulating film 20 may be or include at least one of, for example, silicon oxide, silicon nitride, silicon oxynitride or a low-k material having a dielectric constant smaller than that of silicon oxide.

The lower electrode film 31 may be formed on the lower insulating film 20. The lower electrode film 31 may include a first metal element (M1 of FIGS. 2 to 4). The first metal element M1 may include at least one of, for example, titanium (Ti), tantalum (Ta), tungsten (W), ruthenium (Ru) or iridium (Ir), but is not limited thereto. In some embodiments, the lower electrode film 31 may include a nitride of the first metal element M1.

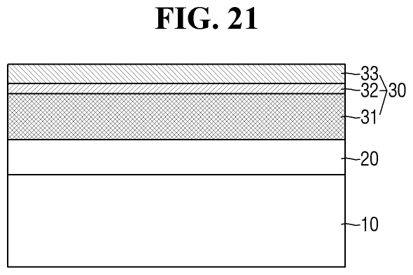

Referring to FIG. 21, the lower insertion electrode film 32 and the lower interface electrode film 33 may be formed on the lower electrode film 31.

Therefore, the lower electrode 30, which includes the lower electrode film 31, the lower insertion electrode film 32 and the lower interface electrode film 33, may be formed on the lower insulating film 20.

For example, a portion of the lower electrode film 31 may be oxidized so that the lower insertion electrode film 32 may be formed. Subsequently, the lower interface electrode film 33 may be formed on the lower insertion electrode film 32.

For another example, the lower interface electrode film 33 may be formed on the lower electrode film 31. While the lower interface electrode film 33 is being formed, oxygen included in the lower interface electrode film 33 may oxidize a portion of the lower electrode film 31. Therefore, the lower insertion electrode film 32 may be formed between the lower electrode film 31 and the lower interface electrode film 33. Unlike the aforementioned example, the lower electrode film 31 may not be oxidized while the lower interface electrode film 33 is being formed.

For another example, a portion of the lower electrode film 31 may be oxidized so that the lower insertion electrode film 32 may be formed. Subsequently, a dopant feed film to supply a doping element (DP of FIG. 3) may be formed on the lower insertion electrode film 32. The doping element DP may be diffused to at least a portion of the lower insertion electrode film 32 by using a diffusion process. As a result, the lower interface electrode film 33 may be formed on the lower electrode film 31.

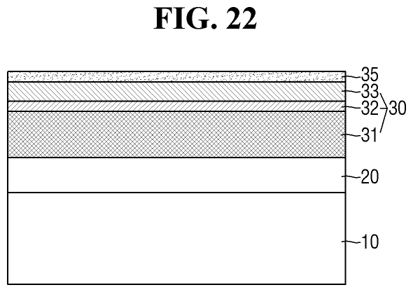

Referring to FIG. 22, the interface blocking film 35 is formed on the lower electrode 30.

The interface blocking film 35 may include a third metal oxide containing a third metal element M3. The third metal element M3 may include a transition metal element. The third metal element M3 may include one of tin (Sn), titanium (Ti), nickel (Ni), cobalt (Co) and molybdenum (Mo), but is not limited thereto.

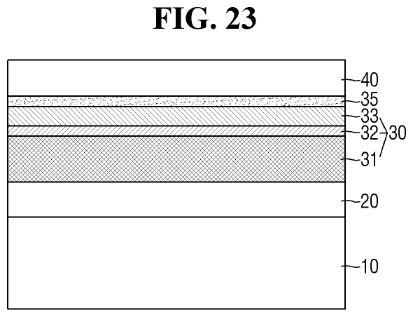

Referring to FIG. 23, the capacitor dielectric film 40 is formed on the interface blocking film 35.

The capacitor dielectric film 40 is in contact with the interface blocking film 35.

Then, the upper electrode 50 is formed on the capacitor dielectric film 40 as shown, e.g., in FIG. 1.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

1. A capacitor structure comprising:
an upper electrode;
a lower electrode including a lower electrode film and a lower interface electrode film;
a capacitor dielectric film between the lower electrode and the upper electrode; and
an interface blocking film between the lower electrode and the capacitor dielectric film, the interface blocking film being in contact with the capacitor dielectric film and the lower interface electrode film,
wherein the interface blocking film includes a first metal oxide containing a first metal element,
the lower interface electrode film includes a second conductive metal oxide containing a second metal element different from the first metal element,
the capacitor dielectric film does not include the first metal oxide, and
a thickness of the lower interface electrode film is greater than a thickness of the interface blocking film.

2. The capacitor structure of claim 1, wherein the lower electrode further includes a lower insertion electrode film disposed between the lower electrode film and the lower interface electrode film,
the lower electrode film includes a third metal element, and
the lower insertion electrode film includes a third metal oxide containing the third metal element.

3. The capacitor structure of claim 2, wherein a thickness of the lower insertion electrode film is smaller than a thickness of the lower interface electrode film.

4. The capacitor structure of claim 2, wherein the third metal element is different from the second metal element.

5. The capacitor structure of claim 2, wherein the third metal element is the same as the second metal element,
the lower interface electrode film includes a first impurity element, and
the first impurity element includes at least one element from among groups 5 to 11 and 15 metal elements.

6. The capacitor structure of claim 5, wherein the lower interface electrode film further includes a second impurity element different from the first impurity element, and
the second impurity element includes at least one of silicon (Si), aluminum (Al), zirconium (Zr) and hafnium (Hf).

7. The capacitor structure of claim 1, wherein the first metal oxide is a single metal oxide.

8. The capacitor structure of claim 1, wherein the first metal element includes at least one of tin (Sn), titanium (Ti), nickel (Ni), cobalt (Co) and molybdenum (Mo).

9. The capacitor structure of claim 1, wherein the second metal element includes at least one of indium (In), ruthenium (Ru), iridium (Ir), vanadium (V), tin (Sn), zinc (Zn), nickel (Ni), tungsten (W) and molybdenum (Mo).

10. The capacitor structure of claim 1, wherein the thickness of the lower interface electrode film is 5 Å to 20 Å, and the thickness of the interface blocking film is 10 Å or less.

11. A capacitor structure comprising:
an upper electrode;
a lower electrode including a lower electrode film, a lower interface electrode film, and a lower insertion electrode film between the lower electrode film and the lower interface electrode film;
a capacitor dielectric film between the lower electrode and the upper electrode; and
an interface blocking film between the lower electrode and the capacitor dielectric film, the interface blocking film being in contact with the capacitor dielectric film and the lower interface electrode film,
wherein the interface blocking film includes a first metal oxide containing a first metal element,
the lower interface electrode film includes a second conductive metal oxide containing a second metal element different from the first metal element,
the lower electrode film includes a third metal element, and
the lower insertion electrode film includes a third metal oxide containing the third metal element.

12. The capacitor structure of claim 11, wherein the second metal element is different from the third metal element.

13. The capacitor structure of claim 11, wherein the third metal element is the same as the second metal element,
the lower interface electrode film includes an impurity element, and
the impurity element includes at least one element from among groups 5 to 11 and 15 metal elements.

14. The capacitor structure of claim 13, wherein the lower interface electrode film includes the impurity element at an atomic percentage of 10 at % or less.

15. The capacitor structure of claim 11, wherein a thickness of the lower interface electrode film is greater than a thickness of the lower insertion electrode film and a thickness of the interface blocking film.

16. The capacitor structure of claim 11, wherein the first metal oxide is a single metal oxide, and
the capacitor dielectric film does not include the first metal oxide.

17. The capacitor structure of claim 11, wherein the first metal element includes at least one of tin (Sn), titanium (Ti), nickel (Ni), cobalt (Co) and molybdenum (Mo), and
the second metal element includes at least one of indium (In), ruthenium (Ru), iridium (Ir), vanadium (V), tin (Sn), zinc (Zn), nickel (Ni), tungsten (W) and molybdenum (Mo).

18. A semiconductor memory device comprising:
a substrate including an active region defined by an element isolation, the active region extending in a first direction and including a first portion and a second portion defined on both sides of the first portion;
a word line extended in a second direction different from the first direction in the substrate and the element isolation film, the word line crossing between the first portion of the active region and the second portion of the active region;
a bit line contact connected to the first portion of the active region;
a bit line connected to the bit line contact on the bit line contact and extended in a third direction different from the first direction and the second direction; and
a capacitor structure including a lower electrode and an interface blocking film, a capacitor dielectric film and an upper electrode, which are sequentially stacked on the lower electrode, the lower electrode being connected to the second portion of the active region,
wherein the lower electrode includes:
a lower electrode film connected to the second portion of the active region, the lower electrode film including a first metal element;
a lower insertion electrode film including a first metal oxide containing the first metal element; and
a lower interface electrode film including a second conductive metal oxide containing a second metal element,
the interface blocking film is in contact with the lower interface electrode film and the capacitor dielectric film, and includes a third metal oxide containing a third metal element different from the second metal element, and
a thickness of the lower interface electrode film is greater than a thickness of the lower insertion electrode film and a thickness of the interface blocking film.

19. The semiconductor memory device of claim 18, wherein the second metal element is different from the first metal element.

20. The semiconductor memory device of claim 18, wherein the second metal element is the same as the first metal element,
the lower interface electrode film includes an impurity element, and
the impurity element includes at least one element from among groups 5 to 11 and 15 metal elements.

21-25. (canceled)
